(19) United States
(12) Patent Application Publication
(10) Pub. No.: US 2024/0241778 A1
(43) Pub. Date: Jul. 18, 2024

(54) IN-SYSTEM MITIGATION OF UNCORRECTABLE ERRORS BASED ON CONFIDENCE FACTORS, BASED ON FAULT-AWARE ANALYSIS

(71) Applicant: Intel Corporation, Santa Clara, CA (US)

(72) Inventors: Shen ZHOU, Shanghai (CN); Cong LI, Shanghai (CN); Kuljit S. BAINS, Olympia, WA (US); Ugonna ECHERUO, Hillsboro, OR (US); Reza E. DAFTARI, Tustin, CA (US); Theodros YIGZAW, Sherwood, OR (US); Mariusz ORIOL, Gdynia (PL)

(21) Appl. No.: 18/562,237

(22) PCT Filed: Dec. 13, 2021
(86) PCT No.: PCT/CN2021/137354

§ 371 Date: Nov. 17, 2023

(51) Int. Cl. G06F 11/07

(52) U.S. Cl. CPC G06F 11/073; G06F 11/079; G06F 11/0793

(57) ABSTRACT

A system (204) can respond to detection of an uncorrectable error (UE) (254) in memory (246) based on fault-aware analysis. The fault-aware analysis enables the system (204) to generate a determination of a specific hardware element of the memory (246) that caused the detected UE (254). In response to detection of a UE (254), the system (204) can correlate a hardware configuration (256) of the memory (246) device with historical data indicating memory (246) faults for hardware elements of the hardware configuration (256). Based on a determination of the specific component that likely caused the UE (254), the system (204) can issue a corrective action for the specific hardware element based on the determination.

### FIELD

Descriptions are generally related to memory systems, and more particular descriptions are related to mitigation operations based on detection of uncorrectable errors.

### BACKGROUND

Memory failure is among the leading causes of server failure and associated downtime in datacenters. Memory errors can be classified as correctable error (CE) or uncorrectable error (UE). CEs refer to transient errors within the memory device data that can be corrected with the application of error checking and correction (ECC). UEs refer to errors that cannot reasonably be corrected with the application of ECC, and result in system failure. Detected (or detectable) uncorrectable errors (DUEs) refer to UEs that can be detected by the ECC but are not correctable with the UE.

UEs and DUEs in memory modules poses a significant cost to consumers and manufacturers, which increases when the error is in a high bandwidth memory (HBM) embedded in a processor, since the entire processor system on a chip (SOC) becomes non-functional due to the memory error.

Some systems will attempt in-field repair actions; however, such detected errors are simply observed errors of an underlying fault in the memory, which is traditionally unknown. Thus, repair actions can be unreliable or inefficient because they can attempt to correct for one error condition, while it is another error condition resulting in the error. For example, the BIOS (basic input/output system) would traditionally spare a row with a UE through post package repair (PPR), even if the UE is the result of a faulty column.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with fault-aware uncorrectable error mitigation.

FIG. 2A is a block diagram of an example of uncorrectable error analysis training.

FIG. 2B is a block diagram of an example of uncorrectable error mitigation based on uncorrectable error analysis.

FIG. 3 is a block diagram of an example of a system architecture for uncorrectable error mitigation.

FIG. 4 is a block diagram of an example of a memory bank architecture.

FIG. 5 is a block diagram of an example of a system for uncorrectable error mitigation with a stacked memory architecture.

FIGS. 6A-6D represent examples of analysis of a specific hardware element cause of a detected uncorrectable error.

FIGS. 7A-7C represent examples of correction actions for a fault-aware system.

FIG. 8 is a flow diagram of an example of a process for performing fault-aware uncorrectable error mitigation.

FIG. 9 is a block diagram of an example of a memory subsystem in which fault-aware uncorrectable error mitigation can be implemented.

FIG. 10 is a block diagram of an example of a computing system in which fault-aware uncorrectable error mitigation can be implemented.

FIG. 11 is a block diagram of an example of a multi-node network in which fault-aware uncorrectable error mitigation can be implemented.

Descriptions of certain details and implementations follow, including non-limiting descriptions of the figures, which may depict some or all examples, and well as other potential implementations.

### DETAILED DESCRIPTION

As described herein, a system can respond to detection of an uncorrectable error (UE) in memory based on fault-aware analysis. The fault-aware analysis enables the system to generate a prediction of a specific hardware element of the memory that caused the detected UE. In statistical analysis, a “prediction” can refer to a conclusion reached by computational analysis. In a computational sense, a computed prediction can identify a prior event or prior cause. In the descriptions below, the computation is generally referred to as fault analysis. A fault “prediction” for a detected UE can refer to the result of a computational analysis that identifies a most likely cause of the error that occurred prior in time. In response to detection of a UE, the system can correlate a hardware configuration of the memory device with historical data indicating memory faults for hardware elements of the hardware configuration. Based on a determination of the specific component that caused the UE, the system can issue a corrective action for the specific hardware element based on the fault analysis.

The fault-aware analysis can refer to UE failure prediction, and specifically, determining a specific component of memory that is most likely the cause of the UE. A fault-aware system can account for the circuit-level architecture of the memory rather than the mere number or frequency of correctable errors (CEs). Observation of error patterns related to circuit structure can enable the system to predict with confidence the component that is the source of the error.

In one example, memory device fault prediction is provided based on correctable error information correlated with system architecture information. Thus, the system can account for rank, bank, row, column, or other information related to the physical organization and structure of the memory in predicting uncorrectable errors. Other systems, including other fault-aware systems, can predict failure to try to prevent UEs. Such operation can be referred to as predictive UE avoidance, attempting to avoid UEs based on fault-aware analysis and prediction. The fault-aware analysis described herein enables a system to perform reactive avoidance of UEs that have already been detected. Thus, the system attempts to avoid the occurrence of another UE. Such a system can work in conjunction with a predictive-avoidance system.

Reactive avoidance based on fault-aware analysis enables the system to generate in-field repair actions based on a confidence factor to mitigate UE-prone faults and provide an indicative post-UE memory health assessment. The health assessment can assist return decisions of memory modules or embedded HBM (high bandwidth memory) SOC packages.

The system can track CE history at the microlevel (e.g., bit, DQ (data pins), row, column, device, rank) to infer whether a certain microlevel memory component (e.g., column fault, row fault) is faulty. After the occurrence of a UE, the system can take the microlevel information as additional evidence. Combining with the faults inferred based on the history, the system can apply analysis (e.g., Bayesian reasoning) to infer which fault caused the UE. Based on determination of the specific component fault, the system can generate an indicative post-UE memory health assessment.

If the system can identify the underlying cause of the UE with a high confidence through the evidence-based reasoning, and the fault can be repaired by a certain RAS (reliability, accessibility, and serviceability) action or corrective action in the field. Examples of corrective action can include repairing a row fault with PPR (post package repair), repairing a bank fault with bank sparing or ADDDC (adaptive double device data correction), or the OS (operating system) can offline a page for a UE that is not recoverable. Based on confidence factor and the analysis, the system can perform high-confidence in-field repair actions by sparing or isolating the identified faulty components. In one example, the system performs the repair actions during runtime, assuming the repair action has runtime repair capability. In one example, if the underlying fault is not field recoverable, the system can mark the UE as field unrecoverable. In one example, if the analysis cannot identify the underlying cause of fault with high confidence, the system can mark the UE as having an unknown cause. For cases of field unrecoverable error or indeterminate fault cause, the system can indicate the cases in a post-UE memory health assessment, allowing an operator to take informed processor return decisions based on the information in the health assessment. The cause of a UE can be indeterminate when the system identifies more than one specific hardware element that is a likely cause of the UE.

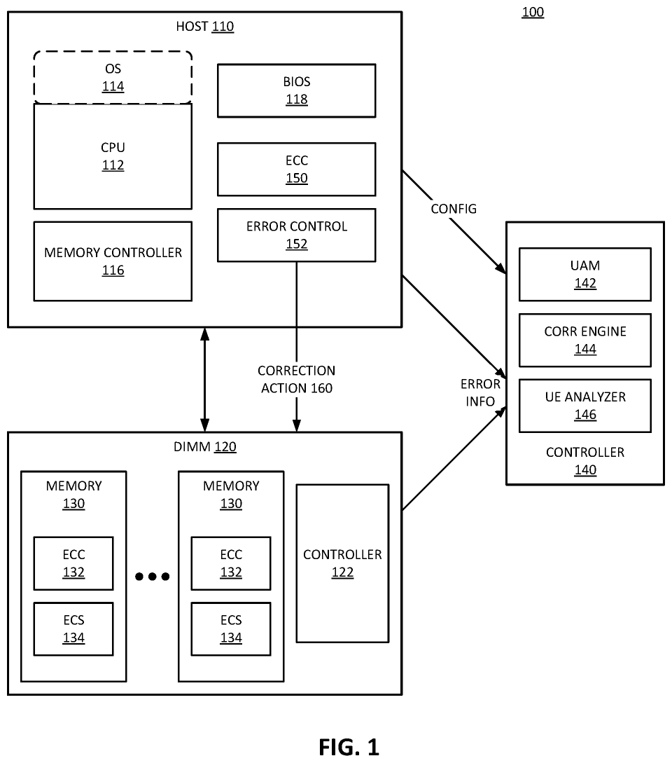

FIG. 1 is a block diagram of an example of a system with fault-aware uncorrectable error mitigation. System 100 illustrates memory coupled to a host. Host 110 represents a host computing platform, such as an SOC (system on a chip). Host 110 includes host processing elements (e.g., processor cores) represented by CPU (central processing unit) 112 to execute operations, and memory controller 116 to manage access to memory 130. Host 110 includes hardware interconnects and driver/receiver hardware to provide the interconnection between host 110 and DIMM (dual inline memory module) 120. In one example, in place of a DIMM, memory 130 can be disposed in an HBM (high bandwidth memory), which refers to a chip or package that includes a stack or a group of tiles of memory dies. Reference to the following descriptions of memory 130 in DIMM 120 can apply to memory 130 in an HBM package or an HBM device with multiple DRAM chips.

DIMM 120 includes memory 130, which represents parallel memory resources coupled to host 110. Memory 130 represents the multiple memory devices of DIMM 120. DIMM 120 includes controller 122, which represent control logic of DIMM 120. In one example, controller 122 is, or is part of, control logic that manages the transfer of commands and data on DIMM 120. For example, controller 122 can be part of a registering clock driver (RCD) or other control logic on DIMM 120. In one example, controller 122 is a separate controller from an RCD.

In one example, memory 130 includes ECC (error checking and correction) 132, which represents on-die ECC, or logic on the memory device to perform error correction for data exchange with host 110. In one example, memory 130 includes ECS (error checking and scrubbing) 134. ECS 134 represents logic on-die on memory 130 to perform periodic error scrubbing of data stored on the memory and can be referred to as a scrubbing engine. Error scrubbing refers to detecting errors, correcting the errors, and writing the corrected data back to the memory array. In one example, memory 130 can detect errors in memory based on ECC 132 and ECS 134.

Host 110 includes ECC 150, which can be part of memory controller 116. In one example, host 110 includes error control 152, which can also be part of memory controller 116. In one example, error control 152 includes a scrubbing engine on the host to perform patrol scrubbing to detect and report errors detected in memory. In one example, error control 152 can manage error correction actions to perform on memory 130 in response to detection of a UE.

Memory controller 116 performs system-level ECC on data from multiple memory devices 130 in parallel, while ECC 132 performs ECC for a single device based on local data. On-die ECC 132 or ECC logic on controller 122 can enable error correction prior to sending data to host 110. In one example, ECS 134 uses ECC 132 to perform error scrubbing. Memory controller 116 can utilize ECC 150 to perform system-level ECC on the data, and the operation of ECC 150 is separate from ECC 132.

ECS 134 or a scrub engine of error control 152 can perform patrol scrubbing, which refers to performance of error checking and scrubbing of all memory 130 within a set period, such as scrubbing the entire memory every 24 hours. Patrol scrubbing can generate CE and UE information during the scrub to indicate correctable errors and hard faults or uncorrectable errors detected in memory 130. Such information can be referred to as a historical error information. When a scrubbing engine detects an error in data of memory 130, in one example, the scrubbing engine provides information to memory controller 116, which can record the data to use for fault analysis.

In one example, system 100 includes controller 140. In one example, controller 140 is part of controller hardware of a hardware platform of system 100. For example, controller 140 can be part of the system board chipset, such as the control circuitry of a system board or motherboard. In one example, controller 140 is part of controller 122. In one example, controller 140 is part of memory controller 116. Controller 140 provides fault-aware analysis of UEs and generates information used to perform corrective action.

In one example, controller 140 represents a fault analysis engine implemented in a microcontroller on a system board. In one example, the microcontroller is a dedicated controller for error management. In one example, the microcontroller is part of system board control hardware, and controller 140 can be implemented as firmware on the microcontroller. Thus, a microcontroller that executes controller 140 can also perform other operations.

In one example, controller 140 includes UAM (uncorrectable error analysis model) 142 and correlation (CORR) engine 144. UAM 142 can represent a model of expected error conditions based on patterns of correctable errors detected in memory data. UAM 142 can be referred to as a failure prediction model or a failure analysis model for the memory. The patterns of correctable errors refer specifically to patterns of errors based on patterns of errors with respect to hardware or memory architecture. Correlation engine 144 can correlate detected errors in historical data with hardware configuration information to identify patterns that are indicative of a high likelihood of uncorrectable error. Correlation engine 144 can correlate historical error information, both recently detected errors and patterns of errors (e.g., based on UAM 142).

In one example, host 110 provides configuration information (CONFIG) to controller 140 to indicate hardware information. In addition to memory hardware information, in one example, the configuration information can include information about the processor, operating system, peripheral features and peripheral controls, or other system configuration information. In one example, memory 130 provide correctable error information (ERROR INFO) to controller 140 to indicate detection of CEs and UEs, to indicate when and where CEs and UEs have occurred. In one example, host 110 provides error information to controller 140 to indicate detection of CEs and UEs in memory 130. In one example, correlation engine 144 correlates the error information, including information about when and where errors have occurred within the memory structure, with configuration information, such as memory configuration and system platform configuration.

In one example, controller 140 correlates detected errors with hardware configuration information for DIMM 120 and memory 130. Such information can be referred to as the memory hardware configuration. In one example, controller 140 correlated detected errors with hardware configuration information for the computer system, which can include memory hardware configuration as well as hardware, software, and firmware configuration of one or more components of the system board or the host hardware platform. The host hardware platform can refer to the configuration of the host processor and other hardware components that enable operation of the computer system. The software or firmware configuration of a system can be included with hardware configuration information to the extent that the software configuration of the hardware causes the same hardware to operate in different ways.

In one example, controller 140 includes UE analyzer 146. UE analyzer 146 represents logic within controller 140 to determine a specific hardware component of memory that caused a detected UE or DUE. In one example, UE analyzer 146 operates after detection of a UE. UE analyzer 146 can use information from UAM 142 and correlation engine 144 to compute a confidence level for multiple hardware components of memory, based on historical error information correlated with the hardware configuration information. The confidence level can indicate a likelihood that a specific component caused a detected UE. The operation of UE analyzer 146 can be considered a prediction in that it determines or predicts based on statistical analysis which component is most likely to have caused the UE. For example, UE analyzer 146 can compute confidence factors for multiple or all hardware component levels of the hardware architecture and determine that the component with a highest (or lowest, depending how the calculation is performed) score is the cause of the fault. In one example, UE analyzer 146 determines one component is the cause of the fault only if its confidence score exceeds all other confidence scores by a threshold. In the case of more than one confidence score within a threshold of each other, UE analyzer 146 can generate an indication that a determination cannot be made (e.g., an “unknown component failure”).

Error control 152 enables host 110 to generate corrective actions in response to detection of a UE. More specifically, controller 140 can indicate the specific component determined to be the cause of a UE to error controller 152. In response to the UE, rather than taking a generic corrective action, error control 152 can take a specific corrective action based on the indication from controller 140 of the cause of the UE. A corrective action can refer to any action or operation performed in system 100 to attempt to prevent the UE from occurring again. A corrective action can be referred to as a correction action or a RAS action.

Correction action 160 represents an action triggered or initiated by error control 152 to address the UE detected. The arrow for correction action 160 is illustrated pointing from error control 152 to DIMM 120 to indicate an operation that affects the availability of memory 130 to attempts to prevent the occurrence of another UE.

Host 110 includes OS (operating system) 114, which executes on CPU 112. OS 114 represents a software platform for system 100. Software programs and processes can execute under OS 114. OS 114 manages memory for software programs that execute on CPU 112. In one example, OS 114 keeps track of memory pages that are available for use by software programs. In one example, correction action 160 can trigger a page offlining operation by OS 114. OS 114 can offline one or more pages for correction action 160. Page offlining means that OS 114 stops using a page of memory (typically 4K of size) to avoid potential memory errors introduced in the page.

In one example, memory 130 includes one or more mechanisms to avoid a portion of memory with a fault, which can be triggered for correction action 160. In one example, memory 130 can perform sparing in response to detection of a UE. Sparing refers to memory 130 mapping a spare row or portion of a row to an address of a row or portion with an uncorrectable error. The sparing can be soft sparing, to temporarily make the mapping, which will remain until the memory is rebooted. The sparing can be hard sparing, setting fuses to permanently remap the address. The sparing can be an entire row or partial row sparing.

In one example, correction action 160 can trigger the application of ADDDC, to apply error correction based on a “buddy” relationship between two separate portions of memory, one of which has the error. ADDDC extends the application of ECC by adding dimension to the portions of memory used for parity logic, which extends the information available to detect and correct an error. In one example, correction action 160 can trigger an application of ECC implemented by ECC 150 and error control 152 to correct for the specific component that caused the detected UE.

In a traditional system, BIOS 118 would perform in-field repair actions based on simple error observations or indicators. In one example of system 100, error control 152 can be part of BIOS 118 to provide fault-aware application of corrective actions. Controller 140 can be part of BIOS 118 to provide the fault-aware analysis.

Controller 140 can perform high-confidence in-field repair actions for certain field-recoverable fatal (uncorrectable) memory errors after their occurrence and providing an indicative post-UE health assessment to assist an informed memory module (or SOC package) return decision. Thus, controller 140 can provide reliable information for a return-to-manufacturer decision in the event of a UE in memory 130.

Controller 140 performs in-field detection of the faulty part including the generation of detailed evidences supporting the fault detection process. In one example, system 100 provides reliable detection of a faulty or defective component and implements high-confidence in-field runtime repair (potentially with reset-less and seamless support). In one example, controller 140 provides memory health information, which can be referred to as health telemetry. In one example, controller 140 provides the telemetry to host 110 through a baseboard management controller (BMC) or through a BIOS-type interface.

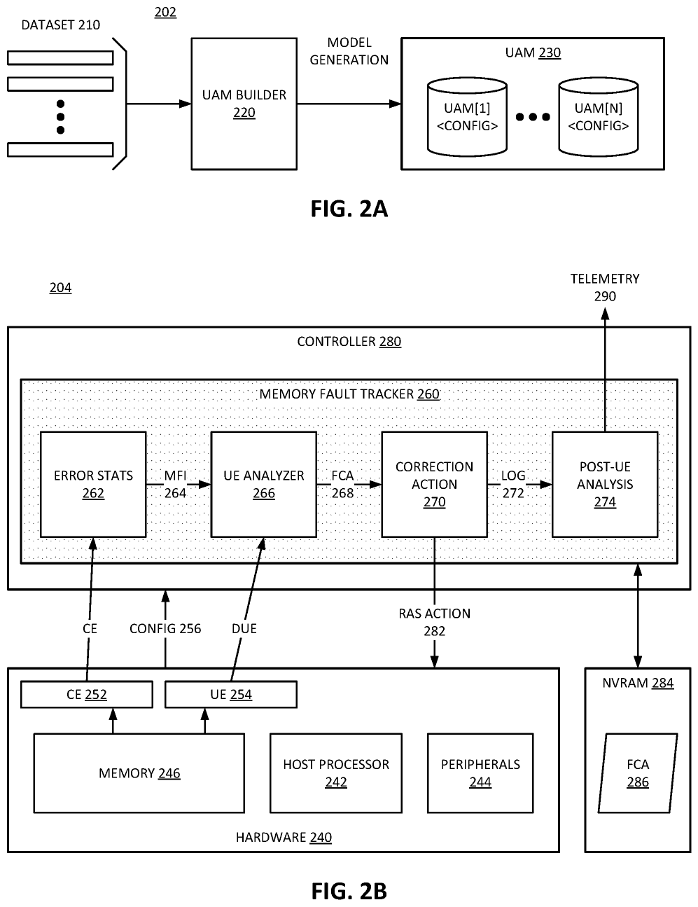

FIG. 2A is a block diagram of an example of uncorrectable error analysis training. System 202 represents elements of a training phase or a training system for prediction of memory fault or an analysis of memory fault due to uncorrectable error. System 202 can provide information for an example of UAM 142 of system 100. In one example, system 202 can be considered an offline prediction or analysis model training, in that dataset 210 represents data for past system operations. An online system refers to a system that is currently operational. System 202 is “operational” in the sense that it is operational to generate the model, but generates the model based on historical data rather than realtime or runtime data.

In one example, system 202 includes dataset 210. Dataset 210 can represent a large-scale CE and UE failure dataset that includes microlevel memory error information. The microlevel memory error information can include indications of failure based on bit, DQ, row, column, device, rank, channel, DIMM, or other configuration, or a combination of information. In one example, dataset 210 includes a timestamp to indicate when errors occurred. In one example, dataset 210 includes hardware configuration information associated with the error dataset. The hardware configuration information can include information such as memory device information, DIMM manufacturer part number, CPU model number, system board details, or other information, or a combination of such information. In one example, dataset 210 can represent information collected from large-scale datacenter implementations.

System 202 includes UAM (UE analysis model) builder 220 to process data from dataset 210 to generate a model that indicates configurations with error patterns that are likely to result in a UE. In one example, UAM builder 220 represents software logic for AI (artificial intelligence) training to generate the model. In this context, AI represents neural network training or other form of data mining to identify patterns of relationship from large data sets. In one example, UAM builder 220 generates UAM 230 for each hardware configuration, based on microlevel (e.g., bit, DQ, row, column, device, rank) CE patterns or indicators. Thus, UAM 230 can include N different UAMs (UAM[1:N]) based on different configuration information (CONFIG).

In one example, UAM 230 includes a separate analysis model for each combination of a CPU model and a DIMM manufacturer or part number. Such granularity for different combinations of CPU model and DIMM part number can identify fault hardware patterns differently, seeing that the different hardware configurations can cause different hardware fault statuses. For example, DIMMs from the same manufacturer or with the same part number but with a different CPU model may implement ECC differently in the memory controller, causing the same faulty hardware status of a DIMM to exhibit different observations due to a different behavior of ECC implementation. A CPU family may provide multiple ECC patterns, allowing a customer to choose the ECC based on the application the customer selects. Similarly, for the same CPU model with a DIMM from a different manufacturer or with a different part number, the faulty status of a DIMM my exhibit different observations due to the different design and implementation of the DIMM hardware. Thus, in one example, system 202 creates analysis models per combination of CPU model and DIMM manufacture or part number to provide improved analysis accuracy performance.

FIG. 2B is a block diagram of an example of uncorrectable error mitigation based on uncorrectable error analysis. System 204 represents an example of a system with UE fault analysis in accordance with an example of system 100. In one example, system 204 implements an example of UAM 230 of system 202 in UE analyzer 266. Whereas system 202 can operate based on historical or stored information, system 204 can be considered a runtime memory failure analysis system in that system 204 operates on runtime or realtime parameters as they occur as well as on historical information.

In one example, system 202 of FIG. 2A provides a machine-learning based uncorrectable memory error analysis mechanism at the level of the memory device. In one example, system 204 utilizes system 202 to generate a runtime prediction or determination of faulty components to determine what component is the likely cause of a detected UE. For example, system 204 can generate a prediction or a determination of a cause of a UE and trigger a correction action specific to the cause of the UE.

System 204 includes controller 280, which can be a dedicated controller, or can represent firmware to execute on a shared controller or hardware shared with other control or management functions in the computer system. In one example, controller 280 is a controller of a host hardware platform, such as hardware 240. The host hardware platform can include a CPU or other host processor 242. Memory 246 can represent multiple memory device or multiple parallel memory resources. In one example, controller 280 represents a controller disposed on a substrate of a computer system. In one example, the substrate is a motherboard. In one example, the substrate is a memory module board. In one example, the substrate is a logic die of an HBM stack (e.g., a control layer on which the memory dies are disposed).

Controller 280 executes memory fault tracker (MFT) 260, which represents an engine to determine a component that caused a UE and trigger a correction action specific to the component, in accordance with any example described. System 204 can enable in-field UE repairing and post-UE health assessment for memory modules. The memory modules can include a DIMM module or other comparable module with multiple memory chip packages on a board, or HBM or other multichip package with multiple dies or tiles on a substrate, all in a memory device package.

Hardware 240 represents the hardware of the system to be monitored for memory errors. Hardware 240 provides hardware configuration (CONFIG) 256 to MFT 260 for error analysis. Configuration 256 represents the specific hardware components and their features and settings. Hardware 240 can include host processor 242, which represents processing resources for a computer system, peripherals 244, and memory 246.

Peripherals 244 represent components and features of hardware 240 that can change the handling of memory errors. Thus, hardware components and software/firmware configuration of the hardware components that can affect how memory errors are handled can be included for consideration in configuration information to send to MFT 260 for memory fault analysis. Examples of peripheral configuration can include peripheral control hub (PCH) configuration, management engine (ME) configuration, quick path interconnect (QPI) capability, or other components or capabilities.

Memory 246 represents the memory resources for which errors can be identified. In one example, system 204 monitors memory 246 to determine when correctable errors and uncorrectable errors occur in the memory. For example, such errors can be detected in a scrubbing operation or as part of an error handling routine.

CE 252 represents CE data for correctable errors detected in data of memory 246. UE 254 represents UE data for detected, uncorrectable errors (DUEs) detected in data of memory 246. In one example, error stats (statistics) 262 monitors CE data for hardware 240. In one example, UE analyzer 266 monitors DUE data for hardware 240.

In one example, UE analyzer 266 can provide prediction of which components experiencing faults are UE-prone. In one example, UE analyzer 266 implements a UE prediction engine based on UAM 230. UE analyzer 266 can store or access UAM 230, which represents a model generated by UAM builder 220 of system 202. In one example, UE analyzer 266 attributes detected CEs to the microlevel components indicated in the configuration information for the system architecture to infer whether the microlevel components are faulty.

UE analyzer 266 generates a prediction of memory faults based on the hardware configuration and correctable error information. The UE prediction is made at the level of hardware. Thus, UE analyzer 266 can generate FCA 268 to indicate specific hardware components of memory 246 that are predicted to fail (e.g., cells, bitlines (columns), wordlines (rows), banks, chips, ranks). In one example, UE analyzer 266 determines whether faulty rows or cells are page-offlining friendly.

In one example, UE analyzer 266 performs analysis on the CEs observed on faulty rows or cells. In one example, UE analyzer 266 includes advanced microlevel fault indicators that built based on the knowledge of ECC coverage used by system 204. In one example, the microlevel fault indicators are built based on knowledge of the error-bit pattern distribution from the DIMM manufacturers to predict whether UEs are likely to happen in the future or not. UE analyzer 266 can apply the fault indicators to pinpoint faulty rows or cells that are UE-prone.

In one example, system 204 stores faulty addresses NVRAM 284. While NVRAM 284 is illustrated, the faulty addresses can be stored in flash memory or other persistent memory. NVRAM 284 enables system 204 to store FCA 286 persistently between boots. Certain memory faults will persist across power cycles of system 204. Thus, FCA 286 in NVRAM 284 can be updated and saved to inform the system of pages that should be offlined between system boots.

In one example, MFT 260 can be an intelligent hardware or software mechanism. MFT 260 can read system configuration (CONFIG 256), track correctable errors (CEs) with micro-level error location information, and count error statistics down to bitlines (or columns), wordlines (or rows), banks, and ranks. Error stats 262 can generate MFI (memory fault indicator) 264, which represents a concise set of indicators tracking the error information. Error stats 262 can send the MFI indicators 264 to UE analyzer 266 to determine how likely the corresponding components (e.g., bitlines or columns, wordlines or rows, banks, ranks) are faulty or not.

When UE 254 is detected in system 204, UE analyzer 266 can read the error location. Based on MFI 264, UE analyzer 266 can perform one or more computations to identify how likely the UE is caused by an underlying faulty component. In one example, UE analyzer 266 applies Bayesian analysis to make the determination. MFT 260 can apply other machine learning or other analysis algorithm to determine the underlying cause of the UE. FCA (faulty component address) 268 represents an identification of the faulty component that UE analyzer 266 determines is the cause of the UE.

When MFT 260 can identify the underlying cause of the UE with a high confidence, it can check whether the identified faulty component can be repaired with certain platform sparing action in the field, such as PPR for row faults, bank sparing for bank faults, or other action. Correction action 270 represents one or more operations determined by MFT 260 in response to the specific error detected at FCA 268. If the component detected as faulty can be repaired, in one example, MFT 260 passes the fault component address with an indication or marking that it is field recoverable.

MFT 260 can perform or trigger a repair action specific to the faulty component identified. RAS action 282 represents the sending or triggering of correction action 270. MFT 260 preferably triggers a runtime correction action when available. Alternatively, RAS action 282 can trigger a repair action for a reboot of hardware 240.

Log 272 represents log information for post-UE analysis, which can include faulty component address information with markings or indications of whether it is field recoverable, and what actions have been taken. In one example, if the faulty component is not field recoverable (e.g., no spare rows remaining for PPR or no spare banks remaining for bank sparing), log 272 can include a mark for the UE as field unrecoverable. In one example, if UE analyzer 266 cannot identify the underlying cause of the UE with high confidence, log 272 can include a mark for the UE as cause unknown.

In one example, MFT 260 includes post-UE analysis 274 for post-UE assessment of the memory health. Post-UE analysis 274 can additionally generate repair action journal log information to indicate the identify components containing faults and repair actions taken.

Post-UE analysis 274 can evaluate the correctness of repair actions by determining whether they succeed in correcting the error. Post-US analysis 274 can generate a proof point for the return-to-manufacturer information. After the operation of post-UE analysis 274, MFT 260 can send telemetry 290 to the host. Telemetry 290 represents evidence based reasoning and faulty component recovery mapping to indicate to the host. Thus, telemetry 290 can include indicative information of post-UE memory health assessment to assist an informed memory module (or HBM-embedded processor) return decision after a fatal memory error happens.

Telemetry 290 can provide a memory health assessment and repair action journal log. In one example, a memory health assessment is categorized as field recoverable (e.g., PPR can repair certain row fault caused UE), field unrecoverable (e.g., column fault caused UE), or cause unknown (e.g., lack of information to identify the UE cause).

MFT 260 can store the post-UE health assessment and log information in NVRAM (nonvolatile random access memory) 284 to track fault information across system power cycles. NVRAM 284 can persistently store identified faulty components information, post-UE memory health assessment, journal logs, and MFI snapshot. Persistent storage of the health assessment and other information enables controller 280 to track memory fault indicators and perform proper RAS actions across system power cycles.

In one example of system 204, controller 280 provides a silicon-based solution that provides the ability to monitor microlevel error information for CEs and DUEs of the memory module, as well as the other related system and memory configurations. In one example, MFT 260 monitors CEs and DUEs and decodes the corresponding microlevel error bit information based on error stats 262 and UE analyzer 266.

In one example, error stats 262 of MFT 260 calculates and updates the microlevel MFIs (as represented by MFI 264) for each memory module when a CE occurs. Such calculations and updates enable MFT 260 to infer whether certain components are faulty. In one example, when a DUE occurs, UE analyzer 266 tries to identify the underlying faulty component that causes the UE based on UE error location and MFIs. The faulty component that causes the UE could be a row fault, a column fault, a bank fault, an unknown fault, or other fault.

In one example, MFT 260, through correction action 270, performs the exact sparing action against the identified faulty component, such as PPR, bank sparing, or other action, based on availability of the actions. In one example, post-UE analysis 274 enables MFT 260 to evaluate the memory health status according to the cause of UE and the applicable platform RAS action. Post-UE analysis 274 can enable MFT 260 to expose the health assessment through telemetry 290, which represents telemetry/logs to assist an informed memory error related return decision of a memory module or the HBM-embedded processor. In one example, MFT 260 creates a journal log for each post-UE assessment. The journal log can include the fault indicators and any repair actions taken, which can be used to evaluate the correctness of repair actions and provide information informing the decision to return the hardware.

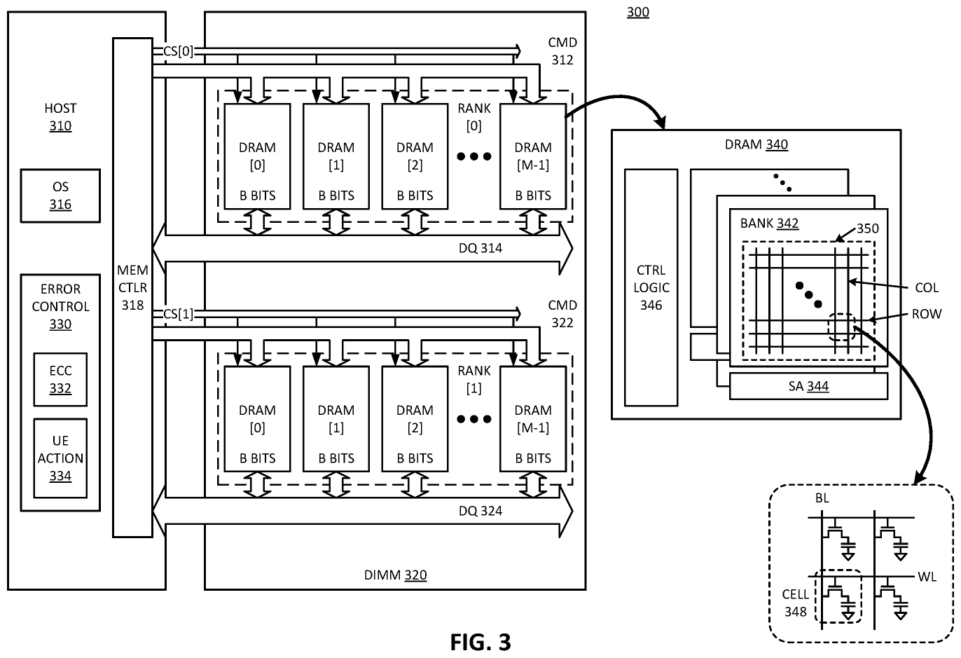

FIG. 3 is a block diagram of an example of a system architecture for uncorrectable error mitigation. System 300 illustrates a computer system in accordance with an example of system 100 or an example of system 204. System 300 includes host 310 connected to DIMM 320. Host 310 represents the host hardware platform for the system in which DIMM 320 operates. Host 310 includes a host processor (not explicitly shown) to execute operations that request access to memory of DIMM 320.

DIMM 320 includes multiple memory devices identified as DRAM (dynamic random access memory) devices or DRAMs connected in parallel to process access commands. DIMM 320 is more specifically illustrated as a two-rank DIMM, with M DRAMs (DRAM[0:M−1]) in each rank, Rank 0 and Rank 1. M can be any integer. Typically, a rank of DRAMs includes data DRAMs to store user data and ECC DRAMs to store system ECC bits and metadata. System 300 does not distinguish DRAM purpose. In one example, the DRAM devices of system 300 represents DRAM devices compatible with a double data rate version 5 (DDR5) standard from JEDEC (Joint Electron Device Engineering Council, now the JEDEC Solid State Technology Association).

The DRAMs of a rank share a command bus and chip select signal lines, and have individual data bus interfaces. CMD (command) 312 represents a command bus for Rank 0 and CMD (command) 322 represents the command bus for Rank 1. The command bus could alternatively be referred to as a command and address bus. CS0 represents a chip select for the devices of Rank 0 and CS1 represents the chip select for the devices of Rank 1. DQ 314 represents the data (DQ) bus for the devices of Rank 0, where each DRAM contributes B bits, where B is an integer, for a total of B*M bits on the DQ bus. DQ 324 represents the data (DQ) bus for the devices of Rank 1.

DRAM 340 provides a representation of an example of details for each DRAM device of system 300. DRAM 340 includes control (CTRL) logic 346, which represents logic to receive and decode commands. Control logic 346 provides internal control signals to respond to commands received on the command bus. DRAM 340 includes multiple banks 342, where the banks represent an organization of the memory array of DRAM 340. Banks 342 have individual access hardware to allow access in parallel or non-blocking access to different banks. The portion labeled as 350 is a subarray of the total memory array of DRAM 340.

The memory array includes rows (ROW) and columns (COL) of memory elements. SA (sense amplifier) 344 represents a sense amplifier to stage data for a read from the memory array or for a write to the memory array. Data can be selected into the sense amplifiers to allow detection of the value stored in a bit cell or memory cell of the array. The dashed box that includes the intersection of the labeled row and column of the memory array. The dashed portion illustrated a typical DRAM cell 348, including a transistor as a control element and a capacitor as a storage element. BL (bitline) is the column signal line and WL (wordline) is the row signal line.

Memory controller (MEM CTLR) 318 represents a memory controller that manages access to the memory resources of DIMM 320. Memory controller 318 provides access commands to the memory devices, including sending data for a write command or receiving data for a read command. Memory controller 318 sends command and address information to the DRAM devices and exchanges data bits with the DRAM devices (either to or from, depending on the command type).

In one example, host 310 includes error control 330 to manage a fault-aware response to UEs. In one example, error control 330 includes ECC 332, which represents ECC at host 310. In one example, ECC 332 is part of memory controller 318. Error control 330 can be or include a memory fault tracker. UE action 334 represents the ability of error control 330 to track memory errors, determine what component is faulty in response to detection of a UE, and generate a specific action based on the component determined to be faulty.

Host 310 includes OS 316, which represents a host operating system on host 310. OS 316 can manage memory space available for programs executed by host 310, and offline pages as a correction action in response to a trigger from UE action 334. In one example, UE action 334 can cause one or more DRAMs to perform full or partial cacheline sparing or sparing of another component (e.g., a bank). The sparing can include the application of ADDDC.

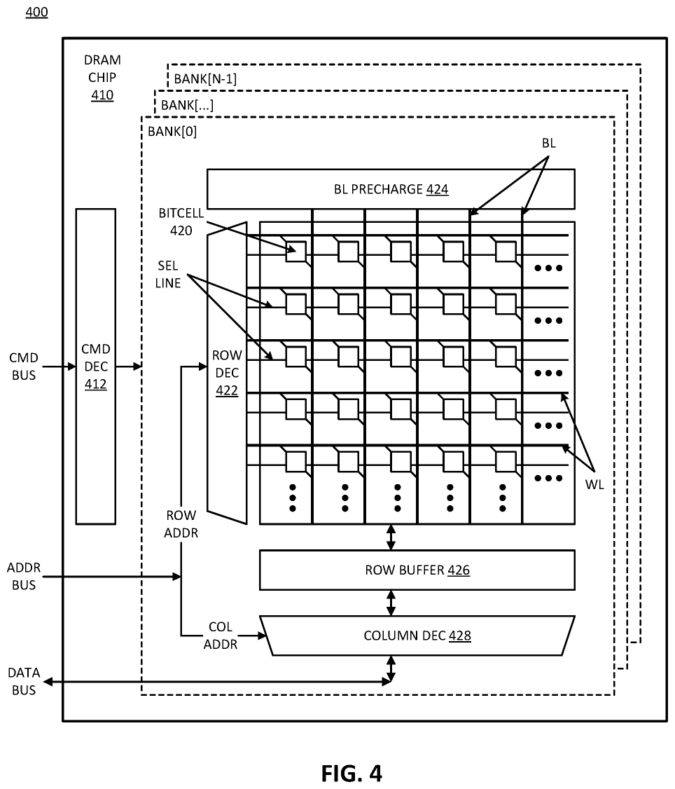

FIG. 4 is a block diagram of an example of a memory bank architecture. System 400 provides an example of a DRAM chip in accordance with an example of system 100 or system 300, where details of the DRAM are illustrated.

Bitcell 420 represents a memory cell or a storage location of the memory array. Bitcell 420 connects to a wordline (WL) and a bitline (BL), with the specific WL/BL location representing an address identifiable by a combination of row (WL) and column (BL) address. The select (SEL) line can enable selection of the wordline.

Row decoder (DEC) 422 represents decoding hardware to select rows or wordlines for read, write, or other access. Row decoder 422 can receive a voltage for a wordline (Vwl) and a voltage for a select line (Vsl) and provide appropriate voltages for selection of a row based on row address (ADDR) information received for an operation.

BL (bitline) precharge 424 represents hardware that can charge one or more selected columns or bitlines for an access operation. BL precharge 424 can charge the bitlines for reading to enable sensing the value stored in a bitcell identified by column and row address. Row buffer 426 represents a buffer for reading or writing bits of the array, and can be implemented as a sense amplifier. Column decoder (DEC) 428 represents hardware to select the output columns or bitlines. Column decoder 428 selects bitlines based on column address information received for an operation.

DRAM chip 410 is illustrated with N banks, Bank[0:(N−1)]. N can be an integer, and is typically a binary number such as 8 or 16. DRAM chip 410 can include command (CMD) decoder (DEC) 412 to decode command information. As illustrated in system 400, the command (CMD) bus is separate from the address (ADDR) bus, although they may be considered a single command and address control bus. They are illustrated as separate in system 400 to indicate that the command and address information can be separated for different controls within the memory device.

Column decoder 428 is shown connecting to the data bus, to receive data for write operations, and to provide data for read operations. For a write operation, data is received on the data bus and placed in row buffer 426 to write to the memory array. For a read operation, data is fetched from the memory array in row buffer 426, to be provided out the data bus to the host.

System 400 illustrates the architecture of a DRAM device. Errors can occur in a column along a bitline, in a row along a wordline, at a specific bit (stuck bit), or at multiple locations rendering a bank defective. A memory fault tracker can monitor the specific architectural components of DRAM chip 410 and determine a correction when a UE is detected.

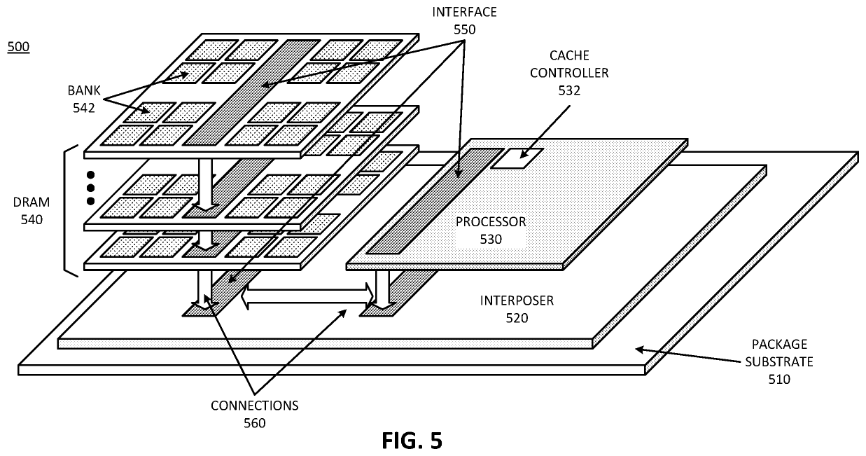

FIG. 5 is a block diagram of an example of a system for uncorrectable error mitigation with a stacked memory architecture. System 500 is an example of a memory system in accordance with system 100, system 200, or system 300. System 500 includes a memory stack architecture monitored by a memory fault tracker.

Package substrate 510 illustrates an SOC package substrate. Package substrate 510 typically includes traces to route to interconnection points of the SOC package. Interposer 520 is integrated onto package substrate 510 and interconnects the processor chip with the memory stack. Interfaces 550 (the dark shaded strips) illustrate hardware interconnection points. The arrows between the various interfaces 550 represent connections 560 from one chip to another through interfaces 550.

Processor 530 represents a processor or central processing unit (CPU) chip or graphics processing unit (GPU) chip to be disposed on interposer 520. Processor 530 performs the computational operations in system 500. In one example, processor 530 includes multiple cores (not specifically shown), which can generate operations that request data to be read from and written to memory. Cache controller 532 represents a circuit on processor 530 to manage interface 550 from processor 530 to memory (DRAMs 540). Cache controller 532 can alternatively be referred to as a memory controller.

DRAMs 540 represent a stack of memory devices, such as an HBM architecture. Each DRAM 540 is illustrated as having 16 banks 542, although other memory configurations can be used. Banks 542 can include memory arrays in accordance with what is illustrated in system 400. Each DRAM 540 can include an interface 550 to connect to interposer 520, and through interposer 520 to processor 530.

In one example, cache controller 532 includes a memory fault tracker controller circuit to perform fault-aware analysis in accordance with any example herein. In one example, the memory fault tracker controller is integrated on interposer 520.

Whether the fault-aware analysis engine is on processor 530, interposer 520, implemented as a separate controller chip integrated onto interposer 520, or elsewhere in system 500, it enables system 500 to perform high-confidence identification of the underlying cause of a UE in DRAMs 540. The analysis engine can generate the component identification from a combined analysis using CE history and identification of a UE. The analysis engine can track memory fault indicators to determine the failure patterns of the memory module or memory stack to infer which underlying component is most likely to be faulty and the cause of the UE. Given the UE result as the fact and the previous CE history as the evidence, the fault analysis evaluates how likely a particular UE is caused by an underlying fault inferred previously. When the analysis engine identifies the faulty component causing the UE with high confidence, based on the faulty component identified, the analysis engine can trigger the performance of a sparing action specific to the repair of the faulty component.

The ability to precisely repair uncorrectable memory errors in the field improves the reliability, availability, and serviceability of a system. Such an ability is especially beneficial for an HBM-embedded SOC, in accordance with an example of system 500, where a memory fault can disable the function of the entire SOC.

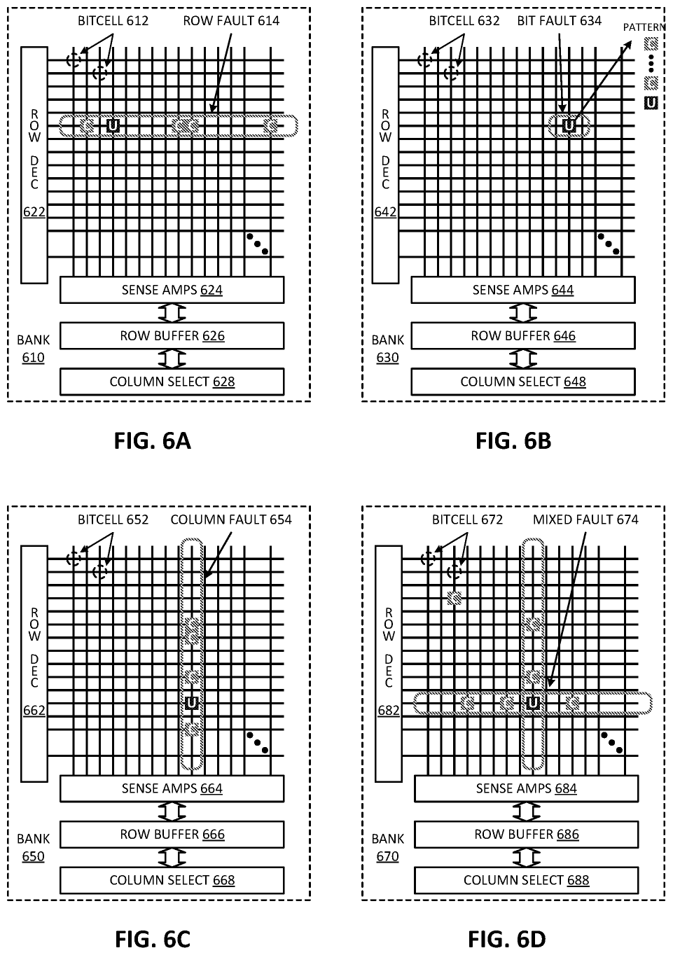

FIGS. 6A-6D represent examples of analysis of a specific hardware element cause of a detected uncorrectable error. The various fault examples illustrate UE cause identification and post-UE health assessment examples for an HBM memory such as the memory stack in system 500, or for a memory module such as the DIMM in system 300.

FIG. 6A represents an example of row fault detection. Bank 610 includes row decoder (DEC) 622 to control the selection of rows or wordlines. Bank 610 includes sense amps 624 to stage data for the memory array of bitcells 612, row buffer 626 to buffer the data between the sense amps and the output hardware, and column select 628 to select portions of the row that will be accessed.

Bank 610 represents a memory bank that includes many CEs, illustrated by the gray squares with a ‘C’ at various bitcells 612. It can be observed that bank 610 includes many CEs in a single row (wordline) of the memory array. It will be understood that not every CE is present at the same time for bank 610. Rather, the CEs illustrated can be detected over time, across multiple accesses of bank 610. Based on the occurrence of multiple CEs in the same row, the system can make a computational determination that the row is faulty. At some point after the occurrence of multiple CEs, the UE is detected on the row, represented by the black square with the ‘U’. Given that the MFT engine has observed multiple faults on the row, it can determine that the UE is caused by the row fault. Thus, for bank 610, the MFT engine can detect row fault 614.

In one example, the MFT engine can trigger a PPR action for the identified faulty row to repair the UE in field. If the repair is successful, the MFT engine can generate a post-UE health assessment of “field recoverable” for row fault 614.

FIG. 6B represents an example of cacheline address fault detection. Bank 630 includes row decoder (DEC) 642 to control the selection of rows or wordlines. Bank 630 includes sense amps 644 to stage data for the memory array of bitcells 632, row buffer 646 to buffer the data between the sense amps and the output hardware, and column select 648 to select portions of the row that will be accessed.

Bank 630 represents a memory bank for which multiple CEs have been detected over time at a specific address. Thus, bank 630 has a pattern of failure at the specific address, with multiple CEs over time (illustrated by the gray squares with a ‘C’), followed by a UE (the black square with a ‘U’) at the same address.

In one example, the address granularity of the detected address fault is a cacheline size. Thus, bank 630 can represent a cacheline fault or a stuck bit fault. Based on repeated CEs at the same address followed by the UE at the address, the MFT engine can determine with high confidence that the memory address is faulty. Bit fault 634 (which could alternatively be referred to as a cacheline fault) represents the error caused by the stuck bit.

In one example, the MFT engine can trigger cacheline sparing to spare a portion of the row. Cacheline sparing refers to sparing only a portion of a row, such as a nibble or a byte. In one example, the MFT engine can trigger a PPR action to spare the entire row containing the faulty address. It will be understood that PPR would use up a spare resource that will not be used with cacheline sparing. If the repair is successful, the MFT engine can generate a post-UE health assessment of “field recoverable” for bit fault 634.

FIG. 6C represents an example of column fault detection. Bank 650 includes row decoder (DEC) 662 to control the selection of rows or wordlines. Bank 650 includes sense amps 664 to stage data for the memory array of bitcells 652, row buffer 666 to buffer the data between the sense amps and the output hardware, and column select 668 to select portions of the row that will be accessed.

Bank 650 represents a memory bank that includes many CEs, illustrated by the gray squares with a ‘C’ at various bitcells 652. It can be observed that bank 650 includes many CEs in a single column (bitline) of the memory array. It will be understood that not every CE is present at the same time for bank 650. Rather, the CEs illustrated can be detected over time, across multiple accesses of bank 650. Based on the occurrence of multiple CEs in the same column, the system can make a computational determination that the column is faulty. At some point after the occurrence of multiple CEs, the UE is detected on the column (the black square with a ‘U’). Given that the MFT engine has observed multiple faults in the column, it can determine that the UE is caused by the column fault. Thus, for bank 650, the MFT engine can detect column fault 654.

It will be understood that PPR or cacheline sparing of the row with the UE will not mitigate column fault 654. In one example, bank sparing is available in the system, and the MFT engine can trigger bank sparing. In one example, the MFT engine can trigger ADDDC. In one example, the MFT engine can trigger page offlining. If a correction action is not available, the MFT engine can generate a post-UE health assessment of “field unrecoverable” for column fault 654.

FIG. 6D represents an example of mixed fault detection. Bank 670 includes row decoder (DEC) 682 to control the selection of rows or wordlines. Bank 670 includes sense amps 684 to stage data for the memory array of bitcells 672, row buffer 686 to buffer the data between the sense amps and the output hardware, and column select 688 to select portions of the row that will be accessed.

Bank 670 represents a memory bank that includes many CEs, illustrated by the gray squares with a ‘C’ at various bitcells 672. It can be observed that bank 670 includes many CEs in a single column (bitline) of the memory array, as well as in a single row (wordline) of the memory array. Even if not every CE is present at the same time for bank 670, the detection of the various CEs over time predicts a potential fault in the column as well as a potential column in the row. At some point after the occurrence of multiple CEs, the UE is detected on the column (the black square with a ‘U’). Given that the MFT engine has observed multiple faults in the column, and multiple faults in the row, it cannot determine a faulty component with high confidence seeing that the UE occurs at the intersection of the row and column. Thus, for bank 670, the MFT engine can detect the UE as mixed fault 674.

Based on fault analysis, bank 670 would appear to have a fault row, a faulty column, and potentially other addresses that are also faulty. Thus, the MFT engine cannot determine whether the UE is caused by the row fault or the column fault. The MFT engine can generate a post-UE health assessment of “cause unknown” for bank 670.

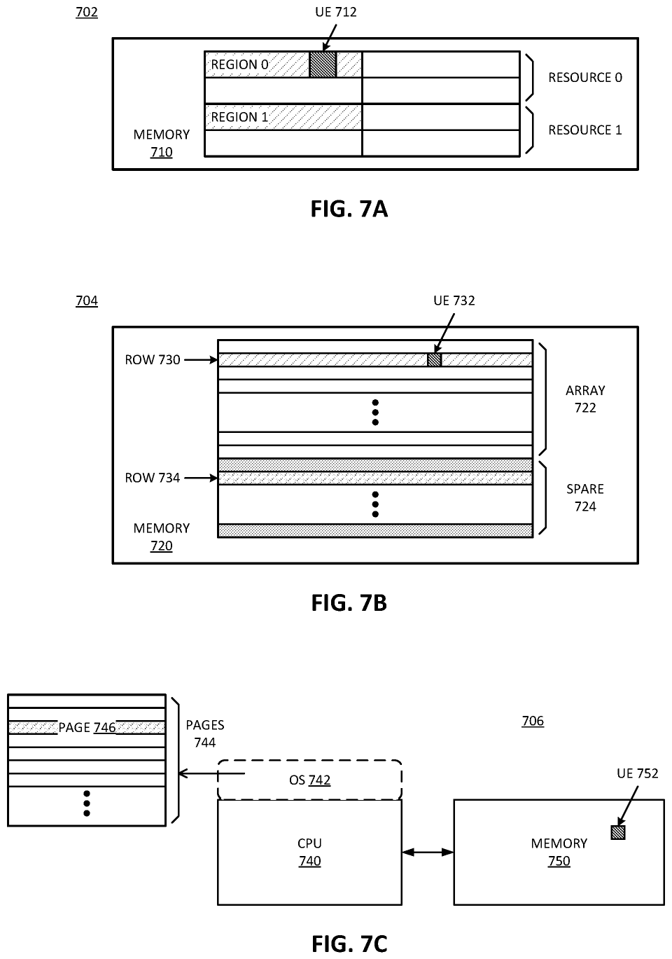

FIG. 7A represents an example of adaptive double device data correction (ADDDC) corrective action for a fault-aware system. System 702 includes memory 710 in which UE 712 has been detected. A memory fault analysis system can determine that UE 712 is caused by a specific fault, and trigger an application of ADDDC to correct the fault to keep memory 710 operational.

With ADDDC, parallel memory resources share data to address a device failure condition. ADDDC can be based on a concept of lockstep data distribution or lockstep configuration or lockstep partnering. Lockstepping traditionally refers to distributing error correction data over multiple memory resources to compensate for a hard failure in one memory resource that prevents deterministic data access to the failed memory resource within the sharing. Lockstepping enables the compensation for hard failure because the distribution of the data results in a lower ECC requirement for error correction.

In system 702, resource 0 and resource 1 represent parallel memory resources. In response to UE 712 in region 0, which can be all or a portion of resource 0, system 702 can perform lockstep data distribution of between resource 0 and resource 1. The application of the ADDDC can enable memory 710 to continue to operate.

FIG. 7B represents an example of a sparing corrective action for a fault-aware system. System 704 includes memory 720 in which UE 732 has been detected in row 730. Array 722 represents the active rows in memory 720, and row 730 is one of the active rows. Spare 724 represents rows of memory that are available to spare a faulty row in array 722. Typically, the number of spare rows is one or many orders of magnitude smaller than the number of active rows. Row 734 is one of the rows of spare 724. In response to detection of UE 732, system 704 can map the address of row 730 to row 734.

FIG. 7C represents an example of an offlining corrective action for a fault-aware system. System 706 includes memory 750 in which UE 752 has been detected. CPU 740 is coupled to memory 750. CPU 740 executes OS (operating system) 742, which keeps track of the pages of memory available in system 706. Pages 744 represents the tracking by OS 742 of the pages of memory. With page offlining, in response to detection of UE 752, page 746 can be offlined in OS 742, and then the page will not be available to programs in system 706. In one example, UE 752 can correspond to multiple pages, and OS 742 can offline multiple pages. Offlining reduces the available memory, but can avoid use of memory resources that would result in system failure.

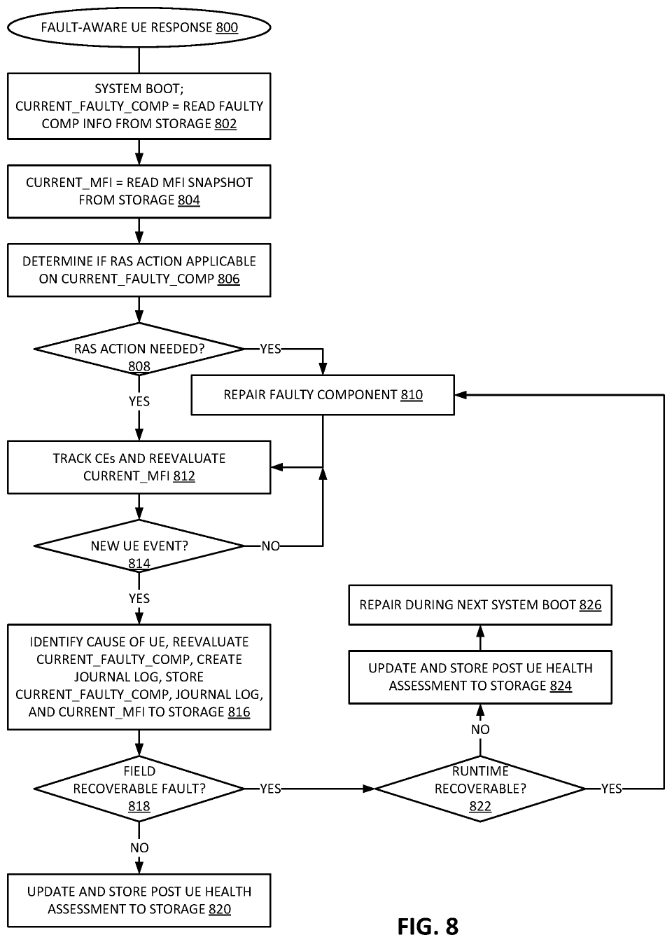

FIG. 8 is a flow diagram of an example of a process for performing fault-aware uncorrectable error mitigation. Process 800 illustrates a flow that can be executed by a system with a memory fault tracker or memory fault analysis engine.

In one example, on system boot, the controller reads faulty component information from storage as a Current_Faulty_Component indication, at 802. In one example, the controller sets a Current_MFI to an MFI snapshot read from storage, 804. The Current_MFI indicates memory fault indicators, to indicate historic information about errors in the memory.

In one example, the controller determines if a RAS action is applicable on a Current_Faulty_Component, at 806, referring to a mitigation action to keep memory operating while avoiding the UE in the faulty component. If there is a RAS action needed, at 808 YES branch, the controller can implement the RAS action to repair the faulty component, at 810. Thus, the controller can maintain faulty component mitigation across system cycles.

In one example, if there are no RAS actions needed for the faulty components, at 808 NO branch, in one example, the controller tracks CEs and reevaluates the Current_MFI based on additional CE information tracked, at 812. The controller will also continue tracking for new errors after applying the RAS action at 810. The memory tracking can include tracking for UEs. If there is not a new UE event detected, at 814 NO branch, the controller can continue the tracking of CEs and reevaluation.

If there is a new UE event detected, at 814 YES branch, in one example, the controller identifies the cause of the UE, reevaluates the Current_Faulty_Component, creates a journal log, and stores the Current_Faulty_Component, journal log, and Current_MFI to storage, at 816. If the new UE is not a field recoverable fault, at 818 NO branch, the controller can update and store the post UE health assessment to storage without implementation of a new RAS action, at 820. The controller can simply mark the error as unrecoverable for later assessment of a returned device.

If the new UE is a field recoverable fault, at 818 YES branch, in one example, the controller determines if the fault can be recovered at runtime. If the fault is runtime recoverable, at 822 YES branch, the controller can implement the appropriate, specific RAS action to recover the UE, repairing the faulty component, at 810, and continuing with error tracking and evaluation, at 812.

If the new UE is not runtime recoverable, at 822 NO branch, in one example, the controller updates and stores a post UE health assessment to storage, at 824, indicating a RAS action to take. The system can repair the UE during the next system boot, at 826. The system can continue to operate without use of the faulty memory component, or the system can immediately schedule a reboot to correct the UE.

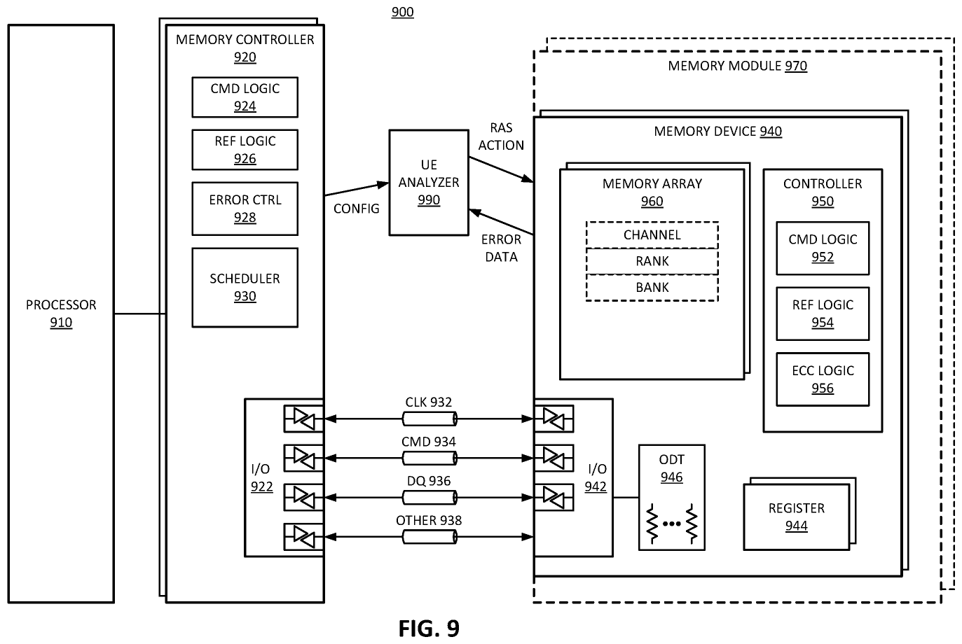

FIG. 9 is a block diagram of an example of a memory subsystem in which fault-aware uncorrectable error mitigation can be implemented. System 900 includes a processor and elements of a memory subsystem in a computing device. System 900 is an example of a system in accordance with an example of system 100.

In one example, system 900 includes UE analyzer 990 or other memory fault tracking engine to determine a component that is a cause of a detected UE. In one example, UE analyzer 990 is part of error control (CTRL) 928 of memory controller 920. Error control 928 can provide memory error management for system 900. UE analyzer 990 can correlate detected errors (ERROR DATA) with hardware configuration information (CONFIG) to determine with high confidence a component that is the cause of the UE. In response to detection of the UE (for example, by ECC logic 956), UE analyzer 990 can generate a RAS action, assuming a faulty component can be determined with high confidence. UE analyzer 990 can also generate a post-UE health assessment to send to memory controller 920 and to store for use across power cycles of memory device 940.

Processor 910 represents a processing unit of a computing platform that may execute an operating system (OS) and applications, which can collectively be referred to as the host or the user of the memory. The OS and applications execute operations that result in memory accesses. Processor 910 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 900 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 (HBM version 2, JESD235C, originally published by JEDEC in January 2020), HBM3 (HBM version 3 currently in discussion by JEDEC), or others or combinations of memory technologies, and technologies based on derivatives or extensions of such specifications.

Memory controller 920 represents one or more memory controller circuits or devices for system 900. Memory controller 920 represents control logic that generates memory access commands in response to the execution of operations by processor 910. Memory controller 920 accesses one or more memory devices 940. Memory devices 940 can be DRAM devices in accordance with any referred to above. In one example, memory devices 940 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 920 manages a separate memory channel, although system 900 can be configured to have multiple channels managed by a single controller, or to have multiple controllers on a single channel. In one example, memory controller 920 is part of host processor 910, such as logic implemented on the same die or implemented in the same package space as the processor.

Memory controller 920 includes I/O interface logic 922 to couple to a memory bus, such as a memory channel as referred to above. I/O interface logic 922 (as well as I/O interface logic 942 of memory device 940) can include pins, pads, connectors, signal lines, traces, or wires, or other hardware to connect the devices, or a combination of these. I/O interface logic 922 can include a hardware interface. As illustrated, I/O interface logic 922 includes at least drivers/transceivers for signal lines. Commonly, wires within an integrated circuit interface couple with a pad, pin, or connector to interface signal lines or traces or other wires between devices. I/O interface logic 922 can include drivers, receivers, transceivers, or termination, or other circuitry or combinations of circuitry to exchange signals on the signal lines between the devices. The exchange of signals includes at least one of transmit or receive. While shown as coupling I/O 922 from memory controller 920 to I/O 942 of memory device 940, it will be understood that in an implementation of system 900 where groups of memory devices 940 are accessed in parallel, multiple memory devices can include I/O interfaces to the same interface of memory controller 920. In an implementation of system 900 including one or more memory modules 970, I/O 942 can include interface hardware of the memory module in addition to interface hardware on the memory device itself. Other memory controllers 920 will include separate interfaces to other memory devices 940.

The bus between memory controller 920 and memory devices 940 can be implemented as multiple signal lines coupling memory controller 920 to memory devices 940. The bus may typically include at least clock (CLK) 932, command/address (CMD) 934, and write data (DQ) and read data (DQ) 936, and zero or more other signal lines 938. In one example, a bus or connection between memory controller 920 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 900 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 920 and memory devices 940. An example of a serial bus technology is 8B10B encoding and transmission of high-speed data with embedded clock over a single differential pair of signals in each direction. In one example, CMD 934 represents signal lines shared in parallel with multiple memory devices. In one example, multiple memory devices share encoding command signal lines of CMD 934, and each has a separate chip select (CS_n) signal line to select individual memory devices.

It will be understood that in the example of system 900, the bus between memory controller 920 and memory devices 940 includes a subsidiary command bus CMD 934 and a subsidiary bus to carry the write and read data, DQ 936. In one example, the data bus can include bidirectional lines for read data and for write/command data. In another example, the subsidiary bus DQ 936 can include unidirectional write signal lines for write and data from the host to memory, and can include unidirectional lines for read data from the memory to the host. In accordance with the chosen memory technology and system design, other signals 938 may accompany a bus or sub bus, such as strobe lines DQS. Based on design of system 900, or implementation if a design supports multiple implementations, the data bus can have more or less bandwidth per memory device 940. For example, the data bus can support memory devices that have either a x4 interface, a x8 interface, a x16 interface, or other interface. The convention “xW,” where W is an integer that refers to an interface size or width of the interface of memory device 940, which represents a number of signal lines to exchange data with memory controller 920. The interface size of the memory devices is a controlling factor on how many memory devices can be used concurrently per channel in system 900 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 940 and memory controller 920 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 940 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 940 represent memory resources for system 900. In one example, each memory device 940 is a separate memory die. In one example, each memory device 940 can interface with multiple (e.g., 2) channels per device or die. Each memory device 940 includes I/O interface logic 942, which has a bandwidth determined by the implementation of the device (e.g., x16 or x8 or some other interface bandwidth). I/O interface logic 942 enables the memory devices to interface with memory controller 920. I/O interface logic 942 can include a hardware interface, and can be in accordance with I/O 922 of memory controller, but at the memory device end. In one example, multiple memory devices 940 are connected in parallel to the same command and data buses. In another example, multiple memory devices 940 are connected in parallel to the same command bus, and are connected to different data buses. For example, system 900 can be configured with multiple memory devices 940 coupled in parallel, with each memory device responding to a command, and accessing memory resources 960 internal to each. For a Write operation, an individual memory device 940 can write a portion of the overall data word, and for a Read operation, an individual memory device 940 can fetch a portion of the overall data word. The remaining bits of the word will be provided or received by other memory devices in parallel.

In one example, memory devices 940 are disposed directly on a motherboard or host system platform (e.g., a PCB (printed circuit board) or substrate on which processor 910 is disposed) of a computing device. In one example, memory devices 940 can be organized into memory modules 970. In one example, memory modules 970 represent dual inline memory modules (DIMMs). In one example, memory modules 970 represent other organization of multiple memory devices to share at least a portion of access or control circuitry, which can be a separate circuit, a separate device, or a separate board from the host system platform. Memory modules 970 can include multiple memory devices 940, and the memory modules can include support for multiple separate channels to the included memory devices disposed on them. In another example, memory devices 940 may be incorporated into the same package as memory controller 920, such as by techniques such as multi-chip-module (MCM), package-on-package, through-silicon via (TSV), or other techniques or combinations. Similarly, in one example, multiple memory devices 940 may be incorporated into memory modules 970, which themselves may be incorporated into the same package as memory controller 920. It will be appreciated that for these and other implementations, memory controller 920 may be part of host processor 910.

Memory devices 940 each include one or more memory arrays 960. Memory array 960 represents addressable memory locations or storage locations for data. Typically, memory array 960 is managed as rows of data, accessed via wordline (rows) and bitline (individual bits within a row) control. Memory array 960 can be organized as separate channels, ranks, and banks of memory. Channels may refer to independent control paths to storage locations within memory devices 940. Ranks may refer to common locations across multiple memory devices (e.g., same row addresses within different devices) in parallel. Banks may refer to sub-arrays of memory locations within a memory device 940. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 940 include one or more registers 944. Register 944 represents one or more storage devices or storage locations that provide configuration or settings for the operation of the memory device. In one example, register 944 can provide a storage location for memory device 940 to store data for access by memory controller 920 as part of a control or management operation. In one example, register 944 includes one or more Mode Registers. In one example, register 944 includes one or more multipurpose registers. The configuration of locations within register 944 can configure memory device 940 to operate in different “modes,” where command information can trigger different operations within memory device 940 based on the mode. Additionally or in the alternative, different modes can also trigger different operation from address information or other signal lines depending on the mode. Settings of register 944 can indicate configuration for I/O settings (e.g., timing, termination or ODT (on-die termination) 946, driver configuration, or other I/O settings).

In one example, memory device 940 includes ODT 946 as part of the interface hardware associated with I/O 942. ODT 946 can be configured as mentioned above, and provide settings for impedance to be applied to the interface to specified signal lines. In one example, ODT 946 is applied to DQ signal lines. In one example, ODT 946 is applied to command signal lines. In one example, ODT 946 is applied to address signal lines. In one example, ODT 946 can be applied to any combination of the preceding. The ODT settings can be changed based on whether a memory device is a selected target of an access operation or a non-target device. ODT 946 settings can affect the timing and reflections of signaling on the terminated lines. Careful control over ODT 946 can enable higher-speed operation with improved matching of applied impedance and loading. ODT 946 can be applied to specific signal lines of I/O interface 942, 922 (for example, ODT for DQ lines or ODT for CA lines), and is not necessarily applied to all signal lines.

Memory device 940 includes controller 950, which represents control logic within the memory device to control internal operations within the memory device. For example, controller 950 decodes commands sent by memory controller 920 and generates internal operations to execute or satisfy the commands. Controller 950 can be referred to as an internal controller, and is separate from memory controller 920 of the host. Controller 950 can determine what mode is selected based on register 944, and configure the internal execution of operations for access to memory resources 960 or other operations based on the selected mode. Controller 950 generates control signals to control the routing of bits within memory device 940 to provide a proper interface for the selected mode and direct a command to the proper memory locations or addresses. Controller 950 includes command logic 952, which can decode command encoding received on command and address signal lines. Thus, command logic 952 can be or include a command decoder. With command logic 952, memory device can identify commands and generate internal operations to execute requested commands.

Referring again to memory controller 920, memory controller 920 includes command (CMD) logic 924, which represents logic or circuitry to generate commands to send to memory devices 940. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 940, memory controller 920 can issue commands via I/O 922 to cause memory device 940 to execute the commands. In one example, controller 950 of memory device 940 receives and decodes command and address information received via I/O 942 from memory controller 920. Based on the received command and address information, controller 950 can control the timing of operations of the logic and circuitry within memory device 940 to execute the commands. Controller 950 is responsible for compliance with standards or specifications within memory device 940, such as timing and signaling requirements. Memory controller 920 can implement compliance with standards or specifications by access scheduling and control.

Memory controller 920 includes scheduler 930, which represents logic or circuitry to generate and order transactions to send to memory device 940. From one perspective, the primary function of memory controller 920 could be said to schedule memory access and other transactions to memory device 940. Such scheduling can include generating the transactions themselves to implement the requests for data by processor 910 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 920 typically includes logic such as scheduler 930 to allow selection and ordering of transactions to improve performance of system 900. Thus, memory controller 920 can select which of the outstanding transactions should be sent to memory device 940 in which order, which is typically achieved with logic much more complex that a simple first-in first-out algorithm. Memory controller 920 manages the transmission of the transactions to memory device 940, and manages the timing associated with the transaction. In one example, transactions have deterministic timing, which can be managed by memory controller 920 and used in determining how to schedule the transactions with scheduler 930.

In one example, memory controller 920 includes refresh (REF) logic 926. Refresh logic 926 can be used for memory resources that are volatile and need to be refreshed to retain a deterministic state. In one example, refresh logic 926 indicates a location for refresh, and a type of refresh to perform. Refresh logic 926 can trigger self-refresh within memory device 940, or execute external refreshes which can be referred to as auto refresh commands) by sending refresh commands, or a combination. In one example, controller 950 within memory device 940 includes refresh logic 954 to apply refresh within memory device 940. In one example, refresh logic 954 generates internal operations to perform refresh in accordance with an external refresh received from memory controller 920. Refresh logic 954 can determine if a refresh is directed to memory device 940, and what memory resources 960 to refresh in response to the command.

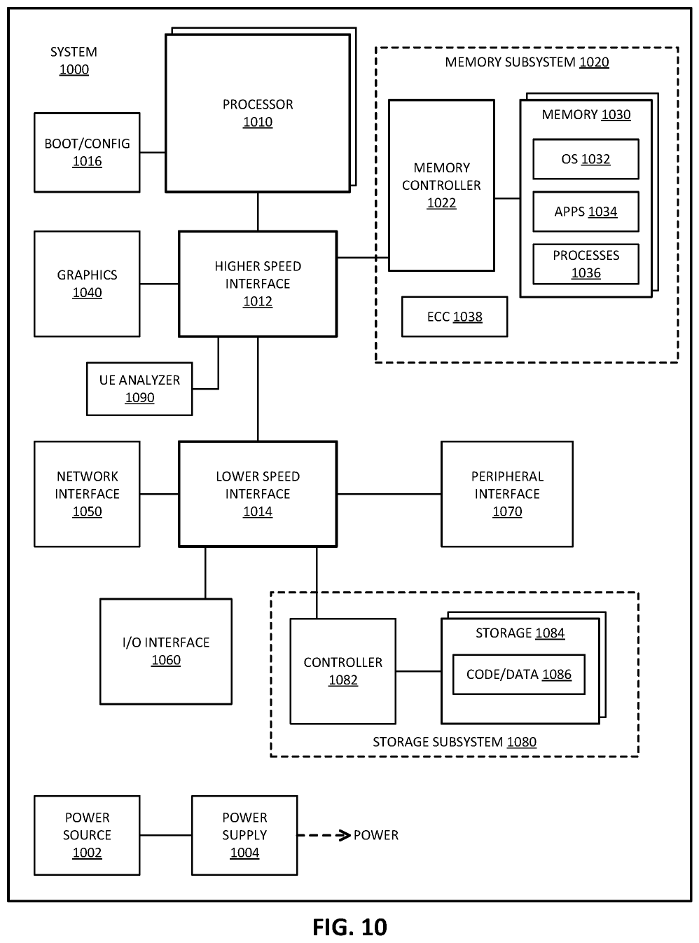

FIG. 10 is a block diagram of an example of a computing system in which fault-aware uncorrectable error mitigation can be implemented. System 1000 represents a computing device in accordance with any example herein, and can be a laptop computer, a desktop computer, a tablet computer, a server, a gaming or entertainment control system, embedded computing device, or other electronic device.

In one example, system 1000 includes UE analyzer 1090 or other memory fault tracking engine to determine a component that is a cause of a detected UE. UE analyzer 1090 can correlate detected errors with hardware configuration information to determine with high confidence a component that is the cause of the UE. In one example, memory subsystem 1020 includes ECC 1038, to perform error checking and correction on data of memory 1030. In one example, ECC 1038 can detect errors as part of a scrubbing operation, which can detect correctable errors or an uncorrectable error. In response to detection of the UE, UE analyzer 1090 can generate a RAS action, assuming a faulty component can be determined with high confidence. UE analyzer 1090 can also generate a post-UE health assessment to send to memory controller 1022 and to store for use across power cycles of memory device 1030.

System 1000 includes processor 1010 can include any type of microprocessor, central processing unit (CPU), graphics processing unit (GPU), processing core, or other processing hardware, or a combination, to provide processing or execution of instructions for system 1000. Processor 1010 can be a host processor device. Processor 1010 controls the overall operation of system 1000, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1000 includes boot/config 1016, which represents storage to store boot code (e.g., basic input/output system (BIOS)), configuration settings, security hardware (e.g., trusted platform module (TPM)), or other system level hardware that operates outside of a host OS. Boot/config 1016 can include a nonvolatile storage device, such as read-only memory (ROM), flash memory, or other memory devices.

In one example, system 1000 includes interface 1012 coupled to processor 1010, which can represent a higher speed interface or a high throughput interface for system components that need higher bandwidth connections, such as memory subsystem 1020 or graphics interface components 1040. Interface 1012 represents an interface circuit, which can be a standalone component or integrated onto a processor die. Interface 1012 can be integrated as a circuit onto the processor die or integrated as a component on a system on a chip. Where present, graphics interface 1040 interfaces to graphics components for providing a visual display to a user of system 1000. Graphics interface 1040 can be a standalone component or integrated onto the processor die or system on a chip. In one example, graphics interface 1040 can drive a high definition (HD) display or ultra high definition (UHD) display that provides an output to a user. In one example, the display can include a touchscreen display. In one example, graphics interface 1040 generates a display based on data stored in memory 1030 or based on operations executed by processor 1010 or both.

Memory subsystem 1020 represents the main memory of system 1000, and provides storage for code to be executed by processor 1010, or data values to be used in executing a routine. Memory subsystem 1020 can include one or more varieties of random-access memory (RAM) such as DRAM, 3DXP (three-dimensional crosspoint), or other memory devices, or a combination of such devices. Memory 1030 stores and hosts, among other things, operating system (OS) 1032 to provide a software platform for execution of instructions in system 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for system 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010, such as integrated onto the processor die or a system on a chip.

While not specifically illustrated, it will be understood that system 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1000 includes interface 1014, which can be coupled to interface 1012. Interface 1014 can be a lower speed interface than interface 1012. In one example, interface 1014 represents an interface circuit, which can include standalone components and integrated circuitry. In one example, multiple user interface components or peripheral components, or both, couple to interface 1014. Network interface 1050 provides system 1000 the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can exchange data with a remote device, which can include sending data stored in memory or receiving data to be stored in memory.

In one example, system 1000 includes one or more input/output (I/O) interface(s) 1060. I/O interface 1060 can include one or more interface components through which a user interacts with system 1000 (e.g., audio, alphanumeric, tactile/touch, or other interfacing). Peripheral interface 1070 can include any hardware interface not specifically mentioned above. Peripherals refer generally to devices that connect dependently to system 1000. A dependent connection is one where system 1000 provides the software platform or hardware platform or both on which operation executes, and with which a user interacts.

In one example, system 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, NAND, 3DXP, or optical based disks, or a combination. Storage 1084 holds code or instructions and data 1086 in a persistent state (i.e., the value is retained despite interruption of power to system 1000). Storage 1084 can be generically considered to be a “memory,” although memory 1030 is typically the executing or operating memory to provide instructions to processor 1010. Whereas storage 1084 is nonvolatile, memory 1030 can include volatile memory (i.e., the value or state of the data is indeterminate if power is interrupted to system 1000). In one example, storage subsystem 1080 includes controller 1082 to interface with storage 1084. In one example controller 1082 is a physical part of interface 1014 or processor 1010, or can include circuits or logic in both processor 1010 and interface 1014.

Power source 1002 provides power to the components of system 1000. More specifically, power source 1002 typically interfaces to one or multiple power supplies 1004 in system 1000 to provide power to the components of system 1000. In one example, power supply 1004 includes an AC to DC (alternating current to direct current) adapter to plug into a wall outlet. Such AC power can be renewable energy (e.g., solar power) power source 1002. In one example, power source 1002 includes a DC power source, such as an external AC to DC converter. In one example, power source 1002 or power supply 1004 includes wireless charging hardware to charge via proximity to a charging field. In one example, power source 1002 can include an internal battery or fuel cell source.

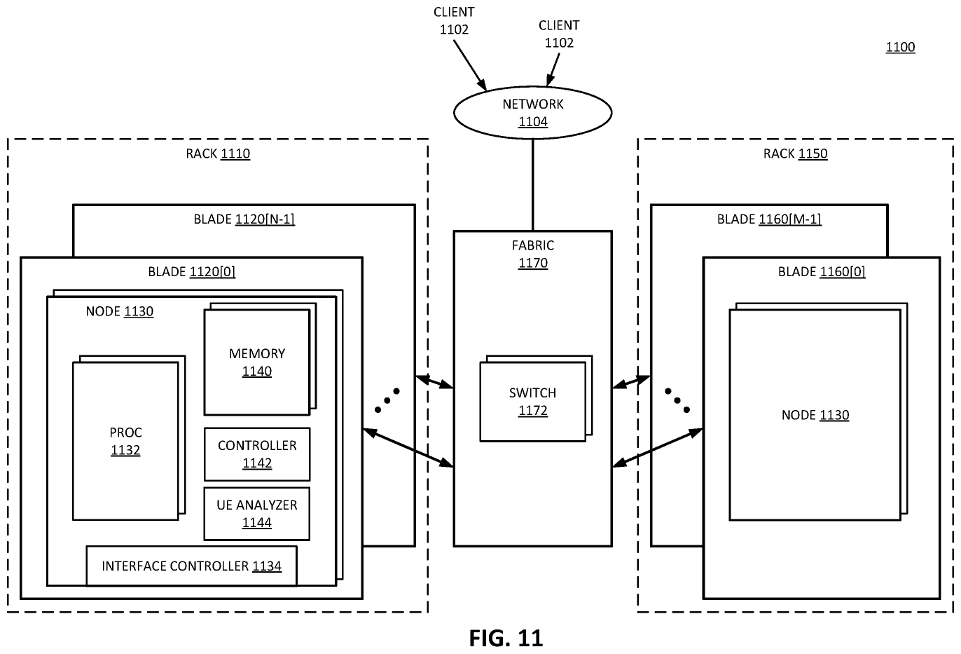

FIG. 11 is a block diagram of an example of a multi-node network in which fault-aware uncorrectable error mitigation can be implemented. In one example, system 1100 represents a server farm. In one example, system 1100 represents a data cloud or a processing cloud. Nodes 1130 of system 1100 represent a system in accordance with an example of system 100. Node 1130 includes memory 1140. Node 1130 includes controller 1142, which represents a memory controller to manage access to memory 1140.

In one example, node 1130 includes UE analyzer 1144 or other memory fault tracking engine to determine a component that is a cause of a detected UE. UE analyzer 1144 can correlate detected errors with hardware configuration information to determine with high confidence a component that is the cause of the UE. In response to detection of the UE, UE analyzer 1144 can generate a RAS action, assuming a faulty component can be determined with high confidence. UE analyzer 1144 can also generate a post-UE health assessment to send to controller 1142 and to store for use across power cycles of memory 1140.

One or more clients 1102 make requests over network 1104 to system 1100. Network 1104 represents one or more local networks, or wide area networks, or a combination. Clients 1102 can be human or machine clients, which generate requests for the execution of operations by system 1100. System 1100 executes applications or data computation tasks requested by clients 1102.

In one example, system 1100 includes one or more racks, which represent structural and interconnect resources to house and interconnect multiple computation nodes. In one example, rack 1110 includes multiple nodes 1130. In one example, rack 1110 hosts multiple blade components 1120. Hosting refers to providing power, structural or mechanical support, and interconnection. Blades 1120 can refer to computing resources on printed circuit boards (PCBs), where a PCB houses the hardware components for one or more nodes 1130. In one example, blades 1120 do not include a chassis or housing or other “box” other than that provided by rack 1110. In one example, blades 1120 include housing with exposed connector to connect into rack 1110. In one example, system 1100 does not include rack 1110, and each blade 1120 includes a chassis or housing that can stack or otherwise reside in close proximity to other blades and allow interconnection of nodes 1130.

System 1100 includes fabric 1170, which represents one or more interconnectors for nodes 1130. In one example, fabric 1170 includes multiple switches 1172 or routers or other hardware to route signals among nodes 1130. Additionally, fabric 1170 can couple system 1100 to network 1104 for access by clients 1102. In addition to routing equipment, fabric 1170 can be considered to include the cables or ports or other hardware equipment to couple nodes 1130 together. In one example, fabric 1170 has one or more associated protocols to manage the routing of signals through system 1100. In one example, the protocol or protocols is at least partly dependent on the hardware equipment used in system 1100.

As illustrated, rack 1110 includes N blades 1120. In one example, in addition to rack 1110, system 1100 includes rack 1150. As illustrated, rack 1150 includes M blades 1160. M is not necessarily the same as N; thus, it will be understood that various different hardware equipment components could be used, and coupled together into system 1100 over fabric 1170. Blades 1160 can be the same or similar to blades 1120. Nodes 1130 can be any type of node and are not necessarily all the same type of node. System 1100 is not limited to being homogenous, nor is it limited to not being homogenous.

For simplicity, only the node in blade 1120[0] is illustrated in detail. However, other nodes in system 1100 can be the same or similar. At least some nodes 1130 are computation nodes, with processor (proc) 1132 and memory 1140. A computation node refers to a node with processing resources (e.g., one or more processors) that executes an operating system and can receive and process one or more tasks. In one example, at least some nodes 1130 are server nodes with a server as processing resources represented by processor 1132 and memory 1140. A storage server refers to a node with more storage resources than a computation node, and rather than having processors for the execution of tasks, a storage server includes processing resources to manage access to the storage nodes within the storage server.

In one example, node 1130 includes interface controller 1134, which represents logic to control access by node 1130 to fabric 1170. The logic can include hardware resources to interconnect to the physical interconnection hardware. The logic can include software or firmware logic to manage the interconnection. In one example, interface controller 1134 is or includes a host fabric interface, which can be a fabric interface in accordance with any example described herein.

Processor 1132 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1140 can be or include memory devices. Node 1130 includes a memory controller, represented by controller 1142, to manage access to memory 1140.

In general with respect to the descriptions herein, in one example, an apparatus to respond to a memory fault includes: a substrate; and a controller disposed on the substrate, the controller to detect an uncorrectable error (UE) in data from a memory device, correlate a hardware configuration of the memory device with historical data indicating memory faults for hardware elements of the hardware configuration to generate a determination of a specific hardware element that caused or likely caused the detected UE, and issue a corrective action for the specific hardware element based on the determination.

In one example of the apparatus, to correlate the hardware configuration with the historical data comprises the controller to monitor correctable errors (CEs) and uncorrectable errors (UEs) for the hardware elements of the hardware configuration. In accordance with any preceding example of the apparatus, in one example, to issue the corrective action comprises the controller to trigger an application of error checking and correction (ECC) to correct for the specific hardware element. In accordance with any preceding example of the apparatus, in one example, to issue the corrective action comprises the controller to trigger an application of adaptive double device data correction (ADDDC) to correct for the specific hardware element. In accordance with any preceding example of the apparatus, in one example, to issue the corrective action comprises the controller to trigger page offlining of the specific hardware element. In accordance with any preceding example of the apparatus, in one example, to issue the corrective action comprises the controller to trigger cacheline sparing for the specific hardware element. In accordance with any preceding example of the apparatus, in one example, to issue the corrective action comprises the controller to trigger row sparing for the specific hardware element. In accordance with any preceding example of the apparatus, in one example, the controller is to store the determination in a nonvolatile memory with memory health information for the memory device. In accordance with any preceding example of the apparatus, in one example, the specific hardware element comprises one or more of a row of memory, a column of memory, or a bit of memory. In accordance with any preceding example of the apparatus, in one example, the substrate comprises a board of a dual inline memory module (DIMM), wherein the controller comprises a controller of the DIMM. In accordance with any preceding example of the apparatus, in one example, the substrate comprises a motherboard, wherein the controller comprises a controller on a motherboard. In accordance with any preceding example of the apparatus, in one example, the memory device comprises a memory module with multiple dynamic random access memory (DRAM) devices. In accordance with any preceding example of the apparatus, in one example, the memory device comprises a high bandwidth memory (HBM) device with multiple dynamic random access memory (DRAM) chips. In accordance with any preceding example of the apparatus, in one example, the system can identify more than one specific component as the likely cause of the EU and mark the EU as having an indeterminate cause.

In general with respect to the descriptions herein, in one example, a system includes: a host hardware platform including a central processing unit (CPU) and multiple memory devices; and a controller coupled to the memory devices, the controller to detect an uncorrectable error (UE) in data from a memory device, correlate a hardware configuration of the memory device with historical data indicating memory faults for hardware elements of the hardware configuration to generate a determination of a specific hardware element that caused or likely caused the detected UE, and issue a corrective action for the specific hardware element based on the determination.

In accordance with any preceding example of the system, in one example, to issue the corrective action comprises the controller to trigger an application of error checking and correction (ECC) to correct for the specific hardware element. In accordance with any preceding example of the system, in one example, to issue the corrective action comprises the controller to trigger an application of adaptive double device data correction (ADDDC) to correct for the specific hardware element. In accordance with any preceding example of the system, in one example, to issue the corrective action comprises the controller to trigger page offlining of the specific hardware element. In accordance with any preceding example of the system, in one example, to issue the corrective action comprises the controller to trigger cacheline sparing for the specific hardware element. In accordance with any preceding example of the system, in one example, to issue the corrective action comprises the controller to trigger row sparing for the specific hardware element. In accordance with any preceding example of the system, in one example, the controller is to store the determination in a nonvolatile memory with memory health information for the memory device. In accordance with any preceding example of the system, in one example, the specific hardware element comprises one or more of a row of memory, a column of memory, or a bit of memory. In accordance with any preceding example of the system, in one example, the substrate comprises a board of a dual inline memory module (DIMM), wherein the controller comprises a controller of the DIMM. In accordance with any preceding example of the system, in one example, the substrate comprises a motherboard, wherein the controller comprises a controller on a motherboard. In accordance with any preceding example of the system, in one example, the system can identify more than one specific component as the likely cause of the EU and mark the EU as having an indeterminate cause. In accordance with any preceding example of the system, in one example, the memory device comprises a memory module with multiple dynamic random access memory (DRAM) devices. In accordance with any preceding example of the system, in one example, the memory device comprises a high bandwidth memory (HBM) device with multiple dynamic random access memory (DRAM) chips. In accordance with any preceding example of the system, in one example, the system includes: a display communicatively coupled to the CPU; a network interface communicatively coupled to a host processor; or a battery to power the system.

In general with respect to the descriptions herein, in one example, a method for analyzing memory device failure includes: detecting an uncorrectable error (UE) in data from a memory device; correlating a hardware configuration of the memory device with historical data indicating memory faults for hardware elements of the hardware configuration to generate a determination of a specific hardware element that caused or likely caused the detected UE; and issuing a corrective action for the specific hardware element based on the determination.

In one example of the method, correlating the hardware configuration with the historical data comprises monitoring correctable errors (CEs) and uncorrectable errors (UEs) for the hardware elements of the hardware configuration. In accordance with any preceding example of the method, in one example, issuing the corrective action comprises triggering one or more of: application of error checking and correction (ECC) to correct for the specific hardware element, application of adaptive double device data correction (ADDDC) to correct for the specific hardware element, page offlining of the specific hardware element, cacheline sparing for the specific hardware element, or row sparing for the specific hardware element. In accordance with any preceding example of the method, in one example, method includes: storing the determination in a nonvolatile memory with memory health information for the memory device. In accordance with any preceding example of the method, in one example, the system can identify more than one specific component as the likely cause of the EU and mark the EU as having an indeterminate cause.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

1.-20. (canceled)

21. An apparatus to respond to a memory fault, comprising:
a substrate; and
a controller disposed on the substrate, the controller to detect an uncorrectable error (UE) in data from a memory device, correlate a hardware configuration of the memory device with historical data indicating memory faults for hardware elements of the hardware configuration to generate a determination of a specific hardware element that likely caused the detected UE, and issue a corrective action for the specific hardware element based on the determination.

22. The apparatus of claim 21, wherein to correlate the hardware configuration with the historical data comprises the controller to monitor correctable errors (CEs) and uncorrectable errors (UEs) for the hardware elements of the hardware configuration.

23. The apparatus of claim 21, wherein to issue the corrective action comprises the controller to trigger an application of adaptive double device data correction (ADDDC) to correct for the specific hardware element.

24. The apparatus of claim 21, wherein to issue the corrective action comprises the controller to trigger page offlining of the specific hardware element, or to trigger cacheline sparing for the specific hardware element.

25. The apparatus of claim 21, wherein to issue the corrective action comprises the controller to trigger row sparing for the specific hardware element.

26. The apparatus of claim 21, wherein the controller is to store the determination in a nonvolatile memory with memory health information for the memory device.

27. The apparatus of claim 21, wherein the controller is to identify more than one specific component as the likely cause of the detected UE and wherein the controller is to generate memory health information that includes a determination that the detected UE has an indeterminate cause.

28. The apparatus of claim 21, wherein the specific hardware element comprises one or more of a row of memory, a column of memory, or a bit of memory.

29. The apparatus of claim 21, wherein the substrate comprises a board of a dual inline memory module (DIMM), wherein the controller comprises a controller of the DIMM.

30. The apparatus of claim 21, wherein the substrate comprises a motherboard, wherein the controller comprises a controller on a motherboard.

31. The apparatus of claim 21, wherein the memory device comprises a memory module with multiple dynamic random access memory (DRAM) devices.

32. The apparatus of claim 21, wherein the memory device comprises a high bandwidth memory (HBM) device with multiple dynamic random access memory (DRAM) chips.

33. A system comprising:
a host hardware platform including a central processing unit (CPU) and multiple memory devices; and
a controller coupled to the memory devices, the controller to detect an uncorrectable error (UE) in data from a memory device, correlate a hardware configuration of the memory device with historical data indicating memory faults for hardware elements of the hardware configuration to generate a determination of a specific hardware element that likely caused the detected UE, and issue a corrective action for the specific hardware element based on the determination.

34. The system of claim 33, wherein to correlate the hardware configuration with the historical data comprises the controller to monitor correctable errors (CEs) and uncorrectable errors (UEs) for the hardware elements of the hardware configuration.

35. The system of claim 33, wherein to issue the corrective action comprises the controller to trigger one or more of: application of error checking and correction (ECC) to correct for the specific hardware element, application of adaptive double device data correction (ADDDC) to correct for the specific hardware element, page offlining of the specific hardware element, cacheline sparing for the specific hardware element, or row sparing for the specific hardware element.

36. The system of claim 33, wherein the controller is to store the determination in a nonvolatile memory with memory health information for the memory device.

37. The system of claim 33, further comprising one or more of:
a display communicatively coupled to the CPU;
a network interface communicatively coupled to a host processor; or
a battery to power the system.

38. A method for analyzing memory device failure, comprising:
detecting an uncorrectable error (UE) in data from a memory device;
correlating a hardware configuration of the memory device with historical data indicating memory faults for hardware elements of the hardware configuration to identify a specific hardware element that likely caused the detected UE; and
issuing a corrective action for the specific hardware element based on the correlating.

39. The method of claim 38, wherein correlating the hardware configuration with the historical data comprises monitoring correctable errors (CEs) and uncorrectable errors (UEs) for the hardware elements of the hardware configuration.

40. The method of claim 38, wherein issuing the corrective action comprises triggering one or more of: application of error checking and correction (ECC) to correct for the specific hardware element, application of adaptive double device data correction (ADDDC) to correct for the specific hardware element, page offlining of the specific hardware element, cacheline sparing for the specific hardware element, or row sparing for the specific hardware element.
